(19) United States
(12) Patent Application Publication
(10) Pub. No.: US 2012/0081982 A1
(43) Pub. Date: Apr. 5, 2012

(54) VERIFYING A DATA PATH IN A SEMICONDUCTOR APPARATUS

(75) Inventors: Jae Ung YI, Icheon-si (KR); Yong Bok AN, Icheon-si (KR)

(73) Assignee: HYNIX SEMICONDUCTOR INC., Icheon-si (KR)

(21) Appl. No.: 12/983,166

(22) Filed: Dec. 31, 2010

(30) Foreign Application Priority Data
Sep. 30, 2010 (KR) 10-2010-0095647

(51) Int. Cl. G11C 7/10; G11C 7/00

(52) U.S. Cl. 365/194; 365/198

(57) ABSTRACT

A semiconductor apparatus includes a memory array configured to store write data transmitted through data transmission lines and transmit stored data to the data transmission line as read data; a data write unit configured to drive the write data to the data transmission lines in response to a data write command; and a data read unit configured to sense the read data transmitted through the data transmission lines in response to a data read command when a data verification signal is deactivated and sense the write data transmitted through the data transmission lines in response to the data write command when the data verification signal is activated.

### CROSS-REFERENCES TO RELATED APPLICATION

The present application claims priority under 35 U.S.C. §119(a) to Korean application number 10-2010-0095647, filed on Sep. 30, 2010, in the Korean Intellectual Property Office, which is incorporated herein by reference in its entirety.

### BACKGROUND

1. Technical Field

The present invention relates to a semiconductor apparatus, and more particularly, to a technology for verifying a data path.

2. Related Art

In general, in order to store data in a memory array of a semiconductor apparatus, write data should be transferred to the memory array through a data input path. The transferred write data is stored in a corresponding memory cell of the memory array. Also, the data stored in the memory array is outputted through a data output path to an external device as output data.

In the case where the reliability of an internal circuit is not secured in an initial development step of a semiconductor apparatus, it is necessary to check if data is precisely transferred to a memory array.

### SUMMARY

In one embodiment of the present invention, a semiconductor apparatus includes: a memory array configured to store write data transmitted through data transmission lines and transmit stored data to the data transmission line as read data; a data write unit configured to drive the write data to the data transmission lines in response to a data write command; and a data read unit configured to sense the read data transmitted through the data transmission lines in response to a data read command when a data verification signal is deactivated and sense the write data transmitted through the data transmission lines in response to the data write command when the data verification signal is activated.

In another embodiment of the present invention, a semiconductor apparatus includes: a data input buffer unit configured to buffer write data inputted through data input/output pads and drive the buffered write data to global data transmission lines; a data write unit configured to drive the write data transmitted through the global data transmission lines to local data transmission lines in response to a data write command; a memory array configured to store the write data transmitted through the local data transmission lines and transmit stored data to the local data transmission lines as read data; a data read unit configured to sense the read data transmitted through the local data transmission lines in response to a data read command when a data verification signal is deactivated and sense the write data transmitted through the local data transmission lines in response to the data write command when the data verification signal is activated; and a data output unit configured to output a signal sensed by the data read unit to the data input/output pads.

In another embodiment of the present invention, a semiconductor apparatus includes: a write control signal generation unit configured to generate a buffer enable signal and a data write signal which are activated for a predetermined time, when a data write command is inputted; a data input buffer unit configured to buffer write data inputted through data input/output pads in response to the buffer enable signal, and drive buffered write data to global data transmission lines; a data write unit configured to drive the write data transmitted through the global data transmission lines to local data transmission lines in response to the data write signal; a memory array configured to store the write data transmitted through the local data transmission lines and transmit stored data to the local data transmission lines as read data; a read control signal generation unit configured to generate a sensing enable signal which is activated for a preselected time, when a data read command is inputted; a read control section configured to output the sensing enable signal as a data read signal when a data verification signal is deactivated and output the data write signal as the data read signal when the data verification signal is activated; a data sensing section configured to sense data transmitted through the local data transmission lines in response to the data read signal; and a data output unit configured to output a signal sensed by the data sensing section to the data input/output pads.

In another embodiment of the present invention, a semiconductor apparatus includes: a data processing unit configured to process input data transmitted through data transmission lines and transmit processed data to the data transmission lines as output data; a data driving unit configured to drive the input data to the data transmission lines in response to a data input command; and a data read unit configured to sense the output data transmitted through the data transmission lines in response to a data output command when a data verification signal is deactivated and sense the input data transmitted through the data transmission lines in response to the data input command when the data verification signal is activated.

In another embodiment of the present invention, a semiconductor apparatus includes: a data input buffer unit configured to buffer input data inputted through data input/output pads and drive buffered input data to first data transmission lines; a data driving unit configured to drive the input data transmitted through the first data transmission lines to second data transmission lines in response to a data input command; a data processing unit configured to process the input data transmitted through the second data transmission lines and transmit processed data to the second data transmission lines as output data; a data read unit configured to sense the output data transmitted through the second data transmission lines in response to a data output command when a data verification signal is deactivated and sense the input data transmitted through the second data transmission lines in response to the data input command when the data verification signal is activated; and a data output unit configured to output a signal sensed by the data read unit to the data input/output pads.

### BRIEF DESCRIPTION OF THE DRAWINGS

Features, aspects, and embodiments are described in conjunction with the attached drawings, in which:

FIG. 1 is a configuration diagram illustrating a semiconductor apparatus in accordance with an embodiment of the present invention;

FIG. 2 is a configuration diagram illustrating an exemplary embodiment of the write control signal generation unit shown in FIG. 1;

FIG. 3 is a configuration diagram illustrating an exemplary embodiment of the read control section shown in FIG. 1; and

FIG. 4 is a timing diagram illustrating internal operations of the semiconductor apparatus shown in FIG. 1; and

FIG. 5 is a configuration diagram illustrating a semiconductor apparatus in accordance with another embodiment of the present invention.

### DETAILED DESCRIPTION

Hereinafter, a semiconductor apparatus according to the present invention will be described below with reference to the accompanying drawings through exemplary embodiments.

For reference, since terms, symbols and signs that are used in drawings and in this detailed description to designate devices, blocks, and so on may be used for detailed units as the occasion demands, it is to be noted that the same terms, symbols and signs may not designate the same devices, blocks, and so on in an entire circuitry. Also, the logic signals of a circuit and binary data values are divided into a high level (H) or a low level (L) in correspondence to voltage levels and may be represented as ‘1’ and ‘0’. Furthermore, as the occasion demands, a high impedance state (a high-Z state) may be defined and described.

An active high signal is said to be asserted when it is in the high level, and an active low signal is said to be asserted when it is in the low level. Additionally, when referring to signals, the terms “asserted” and “activated” may be used interchangeably. Similarly, the terms “deasserted” and “deactivated” may be used interchangeably.

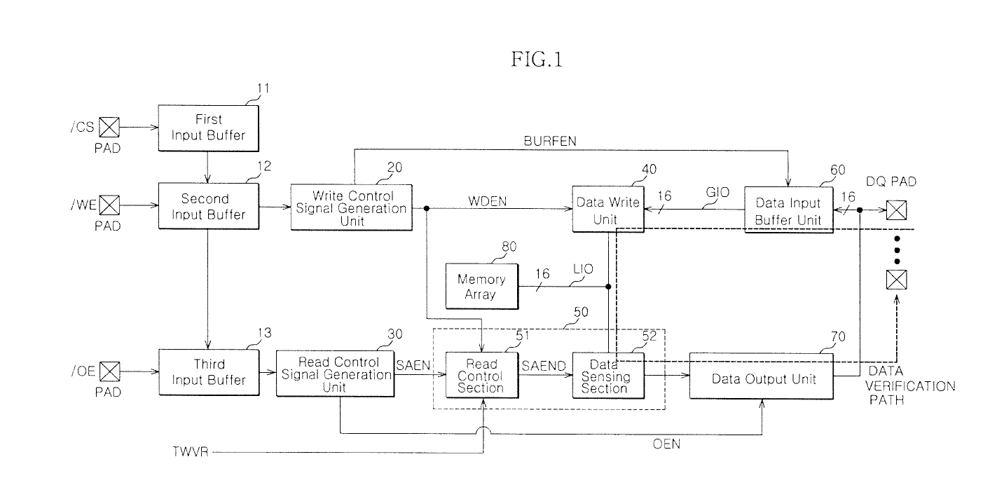

FIG. 1 is a configuration diagram illustrating a semiconductor apparatus in accordance with an embodiment of the present invention.

The semiconductor apparatus in accordance with the present embodiment of the invention includes only a simplified configuration for the sake of clear description.

Referring to FIG. 1, a semiconductor apparatus includes a data input buffer unit 60, a data write unit 40, a memory array 80, a data read unit 50, and a data output unit 70. In the present embodiment of the invention, the semiconductor apparatus further includes first through third input buffers 11, 12 and 13, a write control signal generation unit 20, and a read control signal generation unit 30.

The detailed configuration and the principal operations of the semiconductor apparatus configured as mentioned above will be described below.

The first through third input buffers 11, 12 and 13 are configured to buffer a plurality of command pulse signals /CS, /WE and /OE which are inputted from outside the semiconductor apparatus through pads PAD and output the command pulse signals /CS, /WE and /OE to an internal logic. Specific commands are defined according to combinations of the plurality of command pulse signals /CS, /WE and /OE. In the present embodiment, when a chip select pulse signal /CS is activated among the plurality of command pulse signals /CS, /WE and /OE, and if a write command pulse signal /WE is also activated, it is defined that a data write command is inputted. Similarly, if a read command pulse signal /OE is activated with the chip select pulse signal /CS, it is defined that a data read command is inputted.

The write control signal generation unit 20 is configured to generate a buffer enable signal BURFEN and a data write signal WDEN which are activated for a predetermined time when the data write command is inputted. The activation timing of the buffer enable signal BURFEN may be set to be earlier than the activation timing of the data write signal WDEN.

The read control signal generation unit 30 is configured to generate a sensing enable signal SAEN and an output enable signal OEN which are activated for a preselected time, when the data read command is inputted.

The data input buffer unit 60 is configured to buffer write data inputted through data input/output pads DQ PAD when the buffer enable signal BURFEN is activated and drive the write data to global data transmission lines GIO.

The data write unit 40 is configured to drive the write data transmitted through the global data transmission lines GIO to local data transmission lines LIO in response to the data write command. That is to say, the data write unit 40 drives the write data to the local data transmission lines LIO when the data write signal WDEN is activated.

The memory array 80 is configured to store the write data transmitted through the local data transmission lines LIO and transmit the stored data to the local data transmission lines LIO as read data.

The data read unit 50 is configured to sense the read data transmitted through the local data transmission lines LIO in response to the data read command when a data verification signal TWVR is deactivated. The data read unit 50 is configured to sense the write data transmitted through the local data transmission lines LIO in response to the data write command when the data verification signal TWVR is activated.

In the present embodiment, the data read unit 50 includes a read control section 51 and a data sensing section 52. The read control section 51 is configured to output a data read signal SAEND which is activated in correspondence to the data read command or the data write command, under the control of the data verification signal TWVR. The data sensing section 52 is configured to sense the data transmitted through the local data transmission lines LIO in response to the data read signal SAEND.

Namely, the read control section 51 outputs the sensing enable signal SAEN as the data read signal SAEND when the data verification signal TWVR is deactivated and outputs the data write signal WDEN as the data read signal SAEND when the data verification signal TWVR is activated. When the read control section 51 outputs the data write signal WDEN as the data read signal SAEND, the read control section 51 may delay the data write signal WDEN by a predetermined delay value and output the delayed data write signal WDEN as the data read signal SAEND.

The data transmitted through the local data transmission lines LIO when the data verification signal TWVR is deactivated is read data which is stored in the memory array 80 and is outputted, and the data transmitted through the local data transmission lines LIO when the data verification signal TWVR is activated is write data which is driven from the data write unit 40. Accordingly, the data sensing section 52 senses the read data when the data verification signal TWVR is deactivated and senses the write data when the data verification signal TWVR is activated.

The data output unit 70 is configured to output the signal sensed by the data read unit 50 to the data input/output pads DQ PAD. Therefore, the data output unit 70 outputs the read data stored in the memory array 80 through the data input/output pads DQ PAD to the outside when the data verification signal TWVR is deactivated and outputs the write data driven from the data write unit 40 through the data input/output pads DQ PAD to the outside when the data verification signal TWVR is activated.

The data verification signal TWVR may be defined as a signal which is activated in a test mode. The data verification signal TWVR may be defined as a signal which is set in a mode register set according to an embodiment. Thus, as the write data inputted through a data input path is outputted through a data output path in the test mode, it is possible to test if the data is precisely transmitted through the data input/output paths. In other words, by forming a data verification path, it is possible to test if the data input/output paths are configured correctly. The semiconductor apparatus may perform the above-described operations under the control of a signal set in the mode register set.

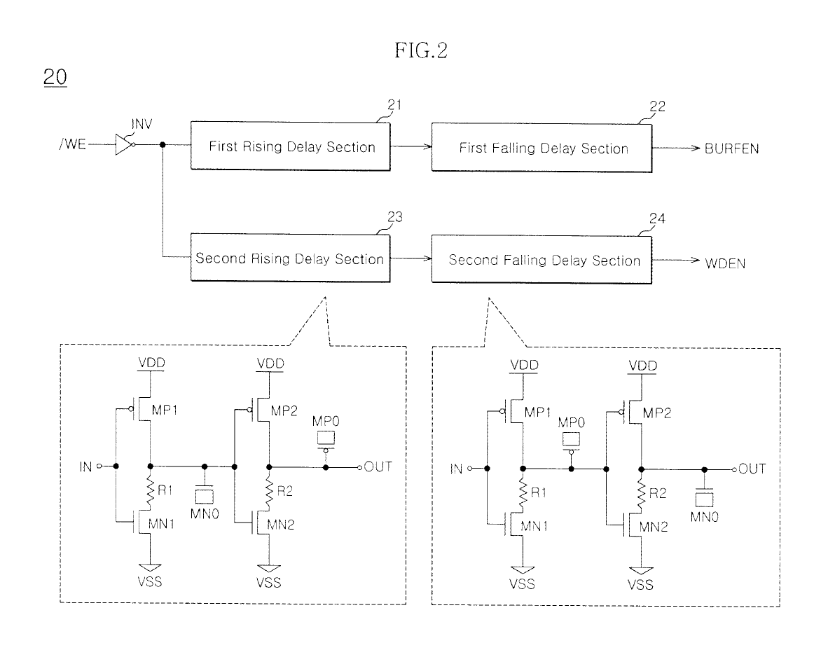

FIG. 2 is a configuration diagram illustrating an exemplary embodiment of the write control signal generation unit shown in FIG. 1.

Referring to FIG. 2, the write control signal generation unit 20 includes a signal inversion section INV, a first rising delay section 21, a first falling delay section 22, a second rising delay section 23, and a second falling delay section 24.

The signal inversion section INV is configured to invert the write command pulse signal /WE and output a resultant signal. The first rising delay section 21 is configured to delay the rising timing of the signal outputted from the signal inversion section INV and output a resultant signal. The first falling delay section 22 is configured to delay the falling timing of the signal outputted from the first rising delay section 21 and output the buffer enable signal BURFEN.

The second rising delay section 23 is configured to delay the rising timing of the signal outputted form the signal inversion section INV and output a resultant signal. The second falling delay section 24 is configured to delay the falling timing of the signal outputted from the second rising delay section 23 and output the data write signal WDEN.

The delay value of the second rising delay section 23 may be designed to be greater than the delay value of the first rising delay section 21, and the delay value of the first falling delay section 22 may be designed to be greater than the delay value of the second falling delay section 24. Hence, the buffer enable signal BURFEN is generated to have an activation timing earlier than that of the data write signal WDEN and a longer activation period than the data write signal WDEN.

FIG. 2 also illustrates exemplary embodiments of the second rising delay section 23 and the second falling delay section 24. In other words, the second rising delay section 23 and the second falling delay section 24 are configured to delay a rising edge and a falling edge through RC delay. Accordingly, the activation timings and deactivation timings of output signals are controlled depending upon respective RC delay amounts.

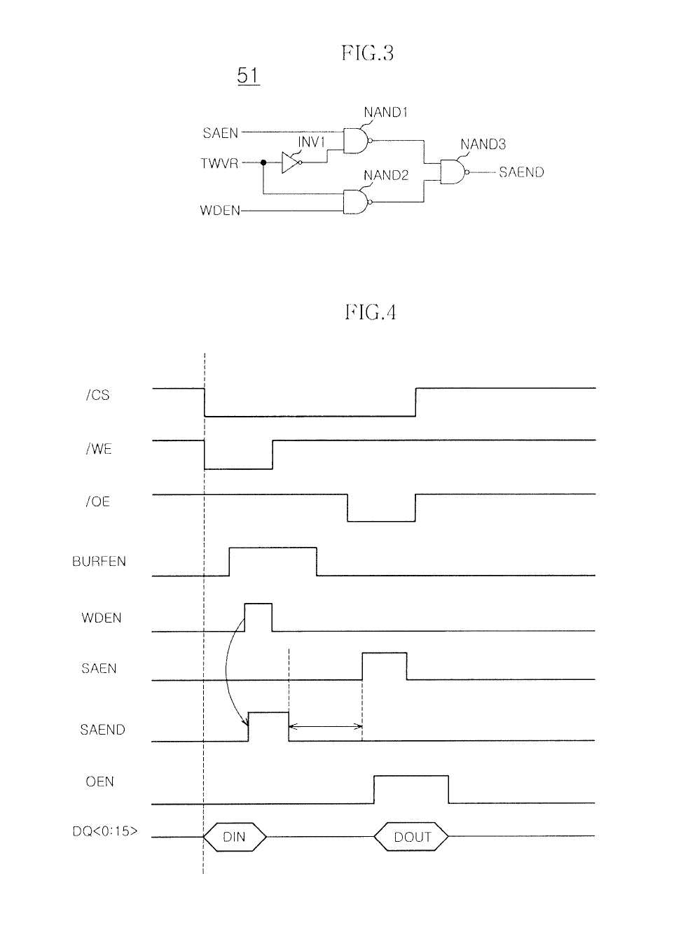

FIG. 3 is a configuration diagram illustrating an exemplary embodiment of the read control section shown in FIG. 1.

Referring to FIG. 3, the read control section 51 includes a first logic stage NAND1 which NANDs the inverted version of the data verification signal TWVR and the sensing enable signal SAEN, a second logic stage NAND2 which NANDs the data verification signal TWVR and the data write signal WDEN, and a third logic stage NAND3 which NANDs the output signals of the first logic stage NAND1 and the second logic stage NAND2 and outputs the data read signal SAEND.

Therefore, when the data verification signal TWVR is deactivated to a low level, the sensing enable signal SAEN is outputted as the data read signal SAEND, and when the data verification signal TWVR is activated to a high level, the data write signal WDEN is outputted as the data read signal SAEND.

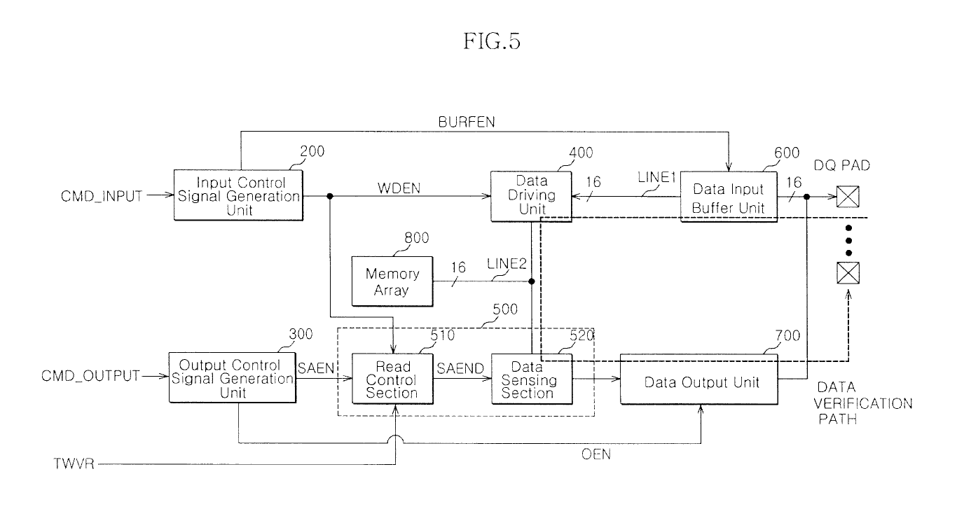

FIG. 4 is a timing diagram illustrating internal operations of the semiconductor apparatus shown in FIG. 1.

Main internal operations of the semiconductor apparatus configured as mentioned above will be described below with reference to the timing diagram of FIG. 4 together with FIGS. 1 through 3.

For reference, while not shown in a drawing, it is assumed that the data verification signal TWVR is activated to the high level.

In the state in which the chip select pulse signal /CS is activated to a low level, if the write command pulse signal /WE is activated to a low level, the data write signal WDEN and the buffer enable signal BURFEN are activated to high levels. The data input buffer unit 60 buffers the write data and transfers the write data to the global data transmission lines GIO when the buffer enable signal BURFEN is activated, and the data write unit 40 transfers the write data transmitted through the global data transmission lines GIO to the local data transmission lines LIO when the data write signal WDEN is activated.

Since the data verification signal TWVR is activated to the high level, the data read signal SAEND is activated to a high level when the data write signal WDEN is activated. The data sensing section 52 senses the data transmitted through the local data transmission lines LIO under the control of the data read signal SAEND, and the sensed data is the write data which is driven from the data write unit 40. Accordingly, the data output unit 70 outputs the write data sensed by the data sensing section 52, through the data input/output pads DQ PAD to the outside under the control of the output enable signal OEN.

FIG. 5 is a configuration diagram illustrating a semiconductor apparatus in accordance with another embodiment of the present invention.

Referring to FIG. 5, a semiconductor apparatus includes a data input buffer unit 600, a data driving unit 400, a data processing unit 800, a data read unit 500, and a data output unit 700. In the present embodiment, the semiconductor apparatus further includes an input control signal generation unit 200, and an output control signal generation unit 300.

The detailed configuration and the principal operations of the semiconductor apparatus configured as mentioned above will be described below.

The input control signal generation unit 200 is configured to generate a buffer enable signal BURFEN and a data write signal WDEN which are activated for a predetermined time, when a data input command CMD_INPUT is inputted. The activation timing of the buffer enable signal BURFEN may be set to be earlier than the activation timing of the data write signal WDEN.

The write control signal generation unit 300 is configured to generate a sensing enable signal SAEN and an output enable signal OEN which are activated for a preselected time, when a data output command CMD_OUTPUT is inputted.

The data input buffer unit 600 is configured to buffer the input data inputted through data input/output pads DQ PAD when the buffer enable signal BURFEN is activated, and drive the buffered input data to first data transmission lines LINE1.

The data driving unit 400 is configured to drive the input data transmitted through the first data transmission lines LINE1 to second data transmission lines LINE2 in response to the data input command CMD_INPUT. That is to say, the data driving unit 400 drives the input data to the second data transmission lines LINE2 when the data write signal WDEN is activated.

The data processing unit 800 is configured to process the input data transmitted through the second data transmission lines LINE2 and transmit the processed data to the second data transmission lines LINE2 as output data. The data processing unit 800 may be defined as a logic for processing digital signals.

The data read unit 500 is configured to sense the output data transmitted through the second data transmission lines LINE2 in response to the data output command CMD_OUTPUT when a data verification signal TWVR is deactivated. Also, the data read unit 500 is configured to sense the input data transmitted through the second data transmission lines LINE2 in response to the data input command CMD_INPUT when the data verification signal TWVR is activated.

In the present embodiment, the data read unit 500 includes a read control section 510 and a data sensing section 520. The read control section 510 is configured to output a data read signal SAEND which is activated in correspondence to the data output command CMD_OUTPUT or the data input command CMD_INPUT, under the control of the data verification signal TWVR. The data sensing section 520 is configured to sense the data transmitted through the second data transmission lines LINE2 in response to the data read signal SAEND.

Namely, the read control section 510 outputs the sensing enable signal SAEN as the data read signal SAEND when the data verification signal TWVR is deactivated and outputs the data write signal WDEN as the data read signal SAEND when the data verification signal TWVR is activated. When the read control section 510 outputs the data write signal WDEN as the data read signal SAEND, the read control section 510 may delay the data write signal WDEN by a predetermined delay value and output the delayed data write signal WDEN as the data read signal SAEND.

The data transmitted through the second data transmission lines LINE2 when the data verification signal TWVR is deactivated is the output data which is processed in the data processing unit 800, and the data transmitted through the second data transmission lines LINE2 when the data verification signal TWVR is activated is the input data which is driven from the data driving unit 400. Accordingly, the data sensing section 520 senses the output data when the data verification signal TWVR is deactivated and senses the input data when the data verification signal TWVR is activated.

The data output unit 700 is configured to output the signal sensed by the data read unit 500 to the data input/output pads DQ PAD. Thus, the data output unit 700 outputs the output data processed by the data processing unit 800 through the data input/output pads PQ PAD to an outside when the data verification signal TWVR is deactivated and outputs the input data driven from the data driving unit 400 through the data input/output pads DQ PAD to the outside when the data verification signal TWVR is activated. In the present embodiment, the data output unit 700 is configured to output the data sensed by the data sensing section 520, under the control of the output enable signal OEN.

The data verification signal TWVR may be defined as a signal which is activated in a test mode. The data verification signal TWVR may be defined as a signal which is set in a mode register set according to an embodiment. Thus, as the input data inputted through a data input path is outputted to the outside through a data output path in the test mode, it is possible to test if the data is correctly transmitted through the data input/output paths. In other words, by forming a data verification path, it is possible to test if the data input/output paths are configured correctly. The semiconductor apparatus may perform the above-described operations under the control of a signal set in the mode register set.

So far, embodiments of the present invention have been described in detail. For reference, embodiments including additional component elements, which are not directly associated with the technical spirit of the present invention, may be exemplified in order to describe the present invention in further detail. Moreover, an active high configuration or an active low configuration for indicating the activated states of signals and circuits may vary depending upon an embodiment. Furthermore, the configurations of transistors may be changed as the occasion demands in order to realize the same function. That is to say, the configurations of a PMOS transistor and an NMOS transistor may be replaced with each other, and as the occasion demands, various transistors may be employed. In addition, the configurations of logic gates may be changed as the occasion demands in order to realize the same function. That is to say, a NANDing element, a NORing element and the like may be configured through various combinations of a NAND gate, a NOR gate, an inverter, and the like. Since these embodiment changes have a large number of cases and can be easily inferred by those skilled in the art, the enumeration thereof will be omitted herein.

While certain embodiments have been described above, it will be understood to those skilled in the art that the embodiments described are by way of example only. Accordingly, the semiconductor apparatus described herein should not be limited based on the described embodiments. Rather, the semiconductor apparatus described herein should only be limited in light of the claims that follow when taken in conjunction with the above description and accompanying drawings.

What is claimed is:

1. A semiconductor apparatus comprising:
a memory array configured to store write data transmitted through data transmission lines and transmit stored data to the data transmission line as read data;
a data write unit configured to drive the write data to the data transmission lines in response to a data write command; and
a data read unit configured to sense the read data transmitted through the data transmission lines in response to a data read command when a data verification signal is deactivated and sense the write data transmitted through the data transmission lines in response to the data write command when the data verification signal is activated.

2. The semiconductor apparatus according to claim 1, further comprising:
a data output unit configured to output a signal sensed by the data read unit.

3. The semiconductor apparatus according to claim 1, wherein the data verification signal comprises a signal activated in a test mode.

4. The semiconductor apparatus according to claim 1, wherein the data verification signal is a signal in a mode register set.

5. The semiconductor apparatus according to claim 1, wherein the data read unit comprises:
a read control section configured to output a data read signal activated in correspondence to the data read command or the data write command, under the control of the data verification signal; and
a data sensing section configured to sense data transmitted through the data transmission lines in response to the data read signal.

6. A semiconductor apparatus comprising:
a data input buffer unit configured to buffer write data inputted through data input/output pads and drive the buffered write data to global data transmission lines;
a data write unit configured to drive the write data transmitted through the global data transmission lines to local data transmission lines in response to a data write command;
a memory array configured to store the write data transmitted through the local data transmission lines and transmit data stored in the memory array to the local data transmission lines as read data;
a data read unit configured to sense the read data transmitted through the local data transmission lines in response to a data read command when a data verification signal is deactivated and sense the write data transmitted through the local data transmission lines in response to the data write command when the data verification signal is activated; and
a data output unit configured to output a signal sensed by the data read unit to the data input/output pads.

7. The semiconductor apparatus according to claim 6, wherein the data verification signal comprises a signal activated in a test mode.

8. The semiconductor apparatus according to claim 6, wherein the data verification signal is a signal set in a mode register set.

9. The semiconductor apparatus according to claim 6, wherein the data read unit comprises:
a read control section configured to output a data read signal activated in correspondence to the data read command or the data write command, under the control of the data verification signal; and
a data sensing section configured to sense data transmitted through the data transmission lines in response to the data read signal.

10. A semiconductor apparatus comprising:
a write control signal generation unit configured to generate a buffer enable signal and a data write signal which are activated for a predetermined time, when a data write command is inputted;
a data input buffer unit configured to buffer write data inputted through data input/output pads in response to the buffer enable signal, and drive buffered write data to global data transmission lines;
a data write unit configured to drive the write data transmitted through the global data transmission lines to local data transmission lines in response to the data write signal;
a memory array configured to store the write data transmitted through the local data transmission lines and transmit data stored in the memory array to the local data transmission lines as read data;
a read control signal generation unit configured to generate a sensing enable signal activated for a preselected time, when a data read command is inputted;
a read control section configured to output the sensing enable signal as a data read signal when a data verification signal is deactivated and output the data write signal as the data read signal when the data verification signal is activated;
a data sensing section configured to sense data transmitted through the local data transmission lines in response to the data read signal; and
a data output unit configured to output a signal sensed by the data sensing section to the data input/output pads.

11. The semiconductor apparatus according to claim 10, wherein an activation timing of the buffer enable signal is earlier than an activation timing of the data write signal.

12. The semiconductor apparatus according to claim 10, wherein the data verification signal comprises a signal which is activated in a test mode.

13. The semiconductor apparatus according to claim 10, wherein the data verification signal is a signal which is set in a mode register set.

14. The semiconductor apparatus according to claim 10, wherein the write control signal generation unit comprises:
a signal inversion section configured to invert a write command pulse signal and output a resultant signal;
a first rising delay section configured to delay a rising timing of a signal outputted from the signal inversion section and output a resultant signal;
a first falling delay section configured to delay a falling timing of a signal outputted from the first rising delay section and output the buffer enable signal;
a second rising delay section configured to delay a rising timing of the signal outputted from the signal inversion section and output a resultant signal; and
a second falling delay section configured to delay a falling timing of a signal outputted from the second rising delay section and output the data write signal,
wherein a delay value of the second rising delay section is greater than a delay value of the first rising delay section, and a delay value of the first falling delay section is greater than a delay value of the second falling delay section.

15. A semiconductor apparatus comprising:
a data processing unit configured to process input data transmitted through data transmission lines and transmit processed data to the data transmission lines as output data;
a data driving unit configured to drive the input data to the data transmission lines in response to a data input command; and
a data read unit configured to sense the output data transmitted through the data transmission lines in response to a data output command when a data verification signal is deactivated and sense the input data transmitted through the data transmission lines in response to the data input command when the data verification signal is activated.

16. The semiconductor apparatus according to claim 15, further comprising:
a data output unit configured to output a signal sensed by the data read unit.

17. The semiconductor apparatus according to claim 15, wherein the data verification signal comprises a signal which is activated in a test mode.

18. The semiconductor apparatus according to claim 15, wherein the data verification signal is a signal which is set in a mode register set.

19. The semiconductor apparatus according to claim 15, wherein the data read unit comprises:
a read control section configured to output a data read signal which is activated in correspondence to the data output command or the data input command, under the control of the data verification signal; and
a data sensing section configured to sense data transmitted through the data transmission lines in response to the data read signal.

20. A semiconductor apparatus comprising:
a data input buffer unit configured to buffer input data inputted through data input/output pads and drive buffered input data to first data transmission lines;
a data driving unit configured to drive the input data transmitted through the first data transmission lines to second data transmission lines in response to a data input command;
a data processing unit configured to process the input data transmitted through the second data transmission lines and transmit processed data to the second data transmission lines as output data;
a data read unit configured to sense the output data transmitted through the second data transmission lines in response to a data output command when a data verification signal is deactivated and sense the input data transmitted through the second data transmission lines in response to the data input command when the data verification signal is activated; and
a data output unit configured to output a signal sensed by the data read unit to the data input/output pads.

21. The semiconductor apparatus according to claim 20, wherein the data verification signal comprises a signal which is activated in a test mode.

22. The semiconductor apparatus according to claim 20, wherein the data verification signal is a signal which is set in a mode register set.

23. The semiconductor apparatus according to claim 20, wherein the data read unit comprises:
a read control section configured to output a data read signal which is activated in correspondence to the data output command or the data input command, under the control of the data verification signal; and
a data sensing section configured to sense data transmitted through the data transmission lines in response to the data read signal.
